(19) United States
(12) Patent Application Publication
(10) Pub. No.: US 2025/0172643 A1
(43) Pub. Date: May 29, 2025

(54) RF COIL, BED DEVICE, AND MAGNETIC RESONANCE IMAGING APPARATUS

(71) Applicant: FUJIFILM Corporation, Tokyo (JP)

(72) Inventors: Kojiro IWASAWA, Tokyo (JP); Hisaaki OCHI, Tokyo (JP); Yosuke OTAKE, Tokyo (JP); Masayoshi DOHATA, Tokyo (JP)

(73) Assignee: FUJIFILM Corporation, Tokyo (JP)

(21) Appl. No.: 18/958,908

(22) Filed: Nov. 25, 2024

(30) Foreign Application Priority Data
Nov. 29, 2023 (JP) 2023-201724

(51) Int. Cl. G01R 33/34

(52) U.S. Cl. CPC G01R 33/34007

(57) ABSTRACT

In an RF coil according to the present disclosure, a first outer peripheral region formed by a plurality of elements of a first fixing belt, which is disposed on a top plate on which a subject is placed, has a tapered shape as being spaced from a first end side of the top plate, a second outer peripheral region formed by a plurality of elements of a second fixing belt, which is disposed on the top plate, has a tapered shape as being spaced from a second end side of the top plate, and the first outer peripheral region and the second outer peripheral region are disposed with phases in a longitudinal direction shifted from each other.

### CROSS-REFERENCE TO RELATED APPLICATION

The present application claims priority under 35 U.S.C. § 119(a) to Japanese Patent Application No. 2023-201724 filed on Nov. 29, 2023, which is hereby expressly incorporated by reference, in its entirety, into the present application.

### BACKGROUND OF THE INVENTION

### 1. Field of the Invention

The present invention relates to an RF coil, a bed device, and a magnetic resonance imaging apparatus, and particularly relates to a technique of fixing an RF coil to a subject.

### 2. Description of the Related Art

A magnetic resonance imaging apparatus (hereinafter referred to as an MRI apparatus) receives a magnetic resonance signal generated in a subject, and reconstructs the received signal to obtain a magnetic resonance image. In such an MRI apparatus, there is a need to fix, to the subject, a radio frequency (RF) coil on which a plurality of elements that receive the magnetic resonance signal are disposed.

JP1998-024025A (JP-H10-024025A) discloses an RF coil unit for MRI including a plurality of RF coils formed to support at least one of transmission or reception of a high-frequency magnetic field for MRI, and an output impedance adjustment circuit that adjusts an output impedance of the plurality of RF coils.

JP2021-159330A discloses an RF coil that receives a magnetic resonance signal from a subject by a plurality of elements including a first element that is stretchable and a second element that is stretchable.

### SUMMARY OF THE INVENTION

In the RF coil, the elements are preferably disposed near the subject without a gap. However, the RF coil of one piece having a fixed size may not cover a variation in a size of the subject. In this case, there is a problem that a sufficient signal-to-noise ratio (SNR) of the magnetic resonance signal cannot be obtained in a range that cannot be covered by the elements.

Further, there is a problem that the number of setting steps is large and a workflow is deteriorated in the RF coil of one piece having a fixed size.

However, in the techniques disclosed in JP1998-024025A (JP-H10-024025A) and JP2021-159330A, these problems cannot be solved.

The present invention has been made in view of such circumstances, and an object thereof is to provide an RF coil, a bed device, and a magnetic resonance imaging apparatus capable of preventing an SNR reduction regardless of a body shape of a subject and easily performing setting to improve a workflow.

In order to achieve the above object, a radio frequency (RF) coil according to a first aspect of the present disclosure is a radio frequency coil for a magnetic resonance imaging apparatus including a top plate on which a subject is placed along a longitudinal direction, the RF coil comprising a first coil unit including a first fixing belt that is disposed on the top plate and is mounted on the subject from a first end side of the top plate in a width direction orthogonal to the longitudinal direction toward a second end side opposite to the first end side, and a plurality of elements that are disposed on the first fixing belt, and a second coil unit including a second fixing belt that is disposed on the top plate and is mounted on the subject in a manner that at least a part of the second fixing belt is overlapped with the first fixing belt from the second end side of the top plate toward the first end side, and a plurality of elements that are disposed on the second fixing belt, in which a first outer peripheral region formed by the plurality of elements of the first coil unit has a tapered shape as being spaced from the first end side of the top plate, a second outer peripheral region formed by the plurality of elements of the second coil unit has a tapered shape as being spaced from the second end side of the top plate, and the first outer peripheral region and the second outer peripheral region are disposed with phases in the longitudinal direction being shifted from each other.

With the RF coil according to the first aspect, it is possible to prevent an SNR reduction regardless of a body shape of the subject and to easily perform setting to improve a workflow.

According to a second aspect of the present disclosure, in the RF coil according to the first aspect, it is preferable that the plurality of elements of the first coil unit form a plurality of the first outer peripheral regions, the plurality of elements of the second coil unit form a plurality of the second outer peripheral regions, and the plurality of the first outer peripheral regions and the plurality of the second outer peripheral regions are alternately disposed along the longitudinal direction.

According to a third aspect of the present disclosure, in the RF coil according to the first or second aspect, it is preferable that each of the plurality of elements has a diameter that decreases as being spaced from the top plate.

According to a fourth aspect of the present disclosure, in the RF coil according to the third aspect, it is preferable that the plurality of elements are disposed at positions at which a line connecting centers of the plurality of elements is parallel to the width direction.

According to a fifth aspect of the present disclosure, in the RF coil according to the third aspect, it is preferable that the plurality of elements of the first coil unit are disposed such that end parts of the plurality of elements are aligned with each other on one side in the longitudinal direction, and the plurality of elements of the second coil unit are disposed such that end parts of the plurality of elements are aligned with each other on the other side in the longitudinal direction.

According to a sixth aspect of the present disclosure, in the RF coil according to the fifth aspect, it is preferable that the first fixing belt and the second fixing belt respectively include guide lines to dispose, in a case where the first fixing belt and the second fixing belt are mounted on the subject, the other side of the first outer peripheral region and the one side of the second outer peripheral region at positions adjacent to each other in a plan view.

According to a seventh aspect of the present disclosure in the RF coil according to the first aspect or the second aspect, it is preferable that each of the plurality of elements has a constant diameter, and is disposed such that the number of elements per unit area decreases as being spaced from the top plate.

According to an eighth aspect of the present disclosure, in the RF coil according to any one of the first to seventh aspects, it is preferable that the first fixing belt includes a guide display showing an appropriate range of a position where the second fixing belt overlaps.

According to a ninth aspect of the present disclosure, in the RF coil according to any one of the first to eighth aspects, it is preferable that the first fixing belt and the second fixing belt include a first surface and a second surface of a pair of surface fasteners with which the first surface and the second surface engage, at positions where the first fixing belt and the second fixing belt are in contact with each other in a case of being mounted on the subject.

In order to achieve the above object, according to a tenth aspect of the present disclosure, there is provided a bed device comprising: a top plate on which a subject is placed, and the RF coil according to any one of the first to ninth aspects.

In order to achieve the above object, according to an eleventh aspect of the present disclosure, there is provided a magnetic resonance imaging apparatus comprising the bed device according to the tenth aspect, a gantry including a magnetic field generation source and having an opening, and a drive mechanism that moves the top plate in the longitudinal direction to cause the top plate to enter the opening of the gantry and exit from the opening of the gantry.

According to the present invention, it is possible to prevent the SNR reduction regardless of the body shape of the subject and to easily perform the setting to improve the workflow.

### BRIEF DESCRIPTION OF THE DRAWINGS

FIG. 1 is a perspective view of an example of an MRI apparatus.

FIG. 2 is a sectional schematic view taken along a line 2-2 of FIG. 1.

FIG. 3 is a perspective view of an example of an MRI apparatus according to a first embodiment.

FIG. 4 is a perspective view of an example of the MRI apparatus.

FIG. 5 is a sectional view taken along a line 5-5 of FIG. 4.

FIGS. 6A and 6B are planar perspective views of a first coil unit and a second coil unit.

FIG. 7 is a view for describing a shape of an outer peripheral region.

FIGS. 8A and 8B are schematic views of a state in which a subject is fixed to a top plate by an RF coil.

FIGS. 9A and 9B are planar perspective views of a disposition of elements in a state in which the subject is fixed to the top plate by the RF coil.

FIGS. 10A and 10B are comparative views for describing effects of the first embodiment.

FIGS. 11A and 11B are planar perspective views of a first coil unit and a second coil unit according to a second embodiment.

FIG. 12 is a view for describing a shape of an outer peripheral region.

FIGS. 13A and 13B are planar perspective views of a disposition of elements in a state in which the subject is fixed to the top plate by the RF coil.

FIGS. 14A and 14B are planar perspective views of a first coil unit and a second coil unit according to a third embodiment.

FIG. 15 is a view for describing a shape of an outer peripheral region.

FIGS. 16A and 16B are planar perspective views of a disposition of elements in a state in which the subject is fixed to the top plate by the RF coil.

### DESCRIPTION OF THE PREFERRED EMBODIMENTS

Hereinafter, preferred embodiments of an RF coil, a bed device, and an MRI apparatus according to the present disclosure will be described with reference to accompanying drawings. In the present specification, the same reference numeral is assigned to the same configuration element and a duplicate description thereof will be omitted as appropriate.

### Apparatus in Related Art

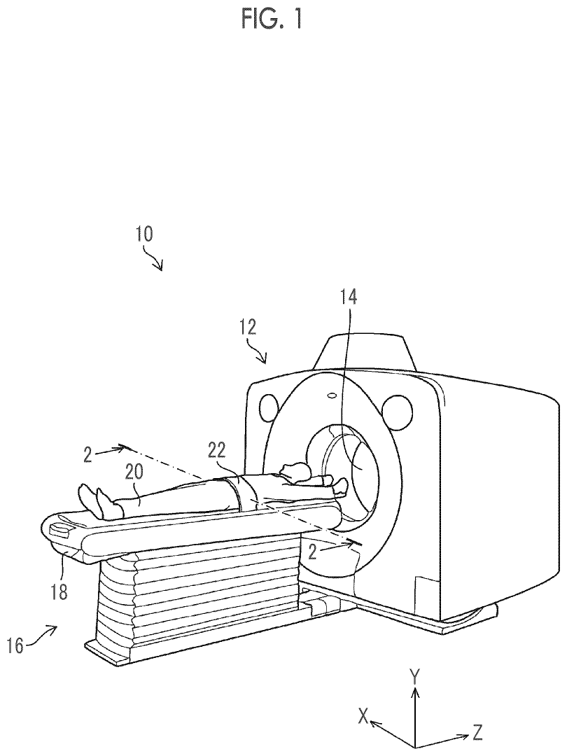

FIG. 1 is a perspective view of an example of an MRI apparatus 10. As shown in FIG. 1, the MRI apparatus 10 comprises a gantry 12 and a bed 16. The gantry 12 has a bore 14 that is a cylindrical examination (imaging) space. Further, an MRI magnet as a magnetic field generation source and various coils are provided in the gantry 12.

The bed 16 is installed to face the bore 14 on a front side of the gantry 12. The bed 16 comprises a top plate 18. A subject 20 is placed on the top plate 18 along a longitudinal direction. The top plate 18 is configured to be movable in an X direction that is a width direction of the top plate 18, a Y direction that is a vertical direction thereof, and a Z direction that is a longitudinal direction, which is orthogonal to the width direction, of the top plate 18.

The MRI apparatus 10 comprises a drive mechanism (not shown) that causes the top plate 18 to move in the Z direction to enter an opening of the gantry 12 and exit from the opening thereof. In the MRI apparatus 10 causes the top plate 18 to move in the bore 14 to set an examination site of the subject 20 to be imaged placed on the top plate 18 at a center of a static magnetic field in the bore 14.

A multi-channel RF coil (hereinafter denoted by RF coil) (not shown) consisting of a plurality of element coils (hereinafter denoted by elements) for receiving a magnetic resonance signal generated in the subject 20 is fixed to the examination site of the subject 20 by a fixing belt 22. In the example shown in FIG. 1, an abdomen of the subject 20 is the examination site, and the RF coil is mounted on the abdomen of the subject 20.

A reception-side cable (not shown) that outputs the magnetic resonance signal received by the RF coil is connected to the RF coil. A reception-side connector (not shown) is connected to an end part of the reception-side cable. The reception-side connector is connected to a bed-side connector of a bed-side cable (not shown). Accordingly, the reception-side cable and the bed-side cable are communicably connected to each other via the connectors.

The bed-side cable is housed in a cable housing portion (not shown) of the bed 16. The magnetic resonance signal of the subject 20 received by the RF coil is transmitted to a signal processing unit (not shown) via the reception-side cable and the bed-side cable. The signal processing unit performs signal processing on the received magnetic resonance signal to convert the received magnetic resonance signal into an image signal.

### Problem 1

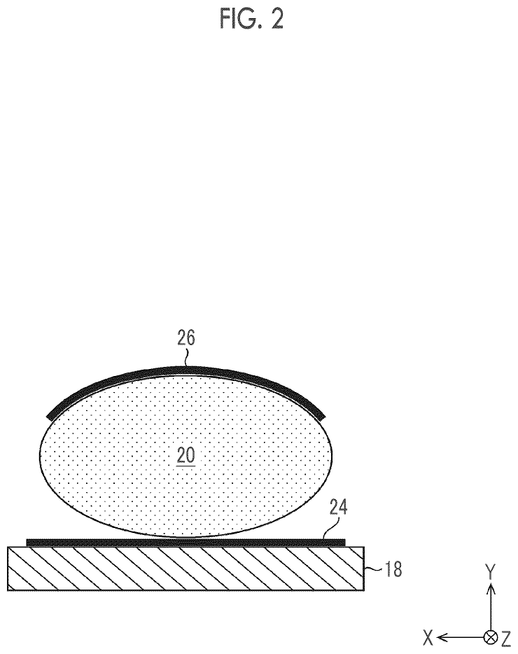

FIG. 2 is a sectional schematic view taken along a line 2-2 of FIG. 1. As shown in FIG. 2, a rear surface coil (spine coil) 24 including a plurality of elements (not shown) is disposed on a surface of the top plate 18 on which the subject 20 is placed. Further, an upper abdomen coil 26 fixed by the fixing belt 22 (not shown in FIG. 2) is disposed on the abdomen of the subject 20 placed on the top plate 18. The rear surface coil 24 and the upper abdomen coil 26 correspond to the RF coils.

In the RF coil, the elements are preferably disposed near the subject 20 without a gap. However, the RF coil of one piece having a fixed size, such as the upper abdomen coil 26, may not cover a variation in a size of the subject 20, and a sufficient SNR may not be obtained in a range that cannot be covered by the elements. In the example shown in FIG. 2, there is a region on a side surface of the subject 20 (a surface on a left-right side of the subject 20 in FIG. 2) that is not covered by any one of the rear surface coil 24 and the upper abdomen coil 26.

### Problem 2

There are many steps of setting the RF coil, and a workflow is deteriorated. First, a user brings the RF coil having a size corresponding to an examination target site of the subject 20 from a coil place (not shown) to the MRI apparatus 10. The user disposes the RF coil on the examination target site of the subject 20 and fixes the RF coil with the fixing belt 22. Further, the user needs to remove the fixing belt 22 from the subject 20 after the examination to return the RF coil to the coil place.

### First Embodiment

### Configuration of RF Coil

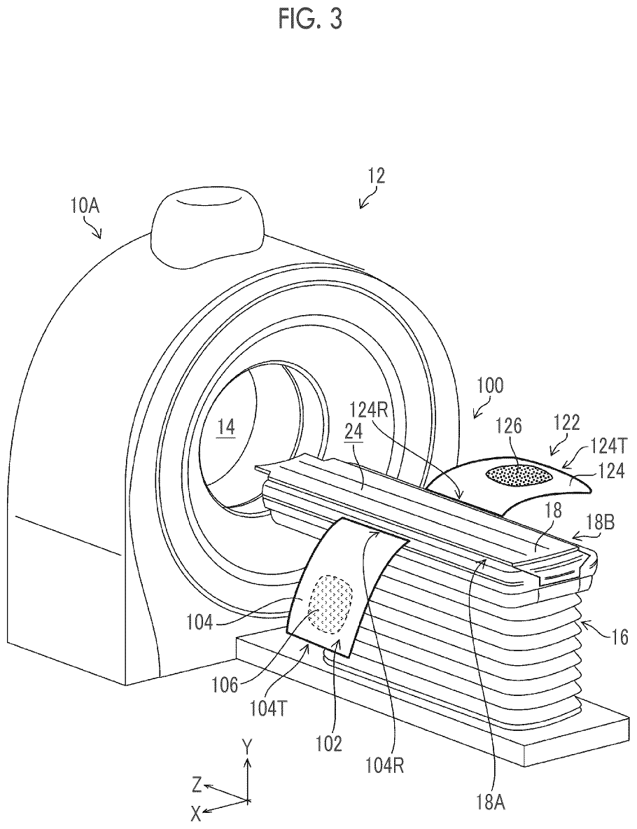

FIG. 3 is a perspective view of an example of an MRI apparatus 10A according to a first embodiment. As shown in FIG. 3, the MRI apparatus 10A comprises an RF coil 100 for the MRI apparatus. The RF coil 100 includes a first coil unit 102 and a second coil unit 122.

The first coil unit 102 comprises a first fixing belt 104. One end part 104R of the first fixing belt 104 is disposed on a first end 18A side (an example of “first end side”, a front side of the top plate 18 in FIG. 3) of the top plate 18 in the X direction, and the other end part 104T thereof is a free end.

The second coil unit 122 comprises a second fixing belt 124. One end part 124R of the second fixing belt 124 is disposed on a second end 18B side (an example of “second end side”, a back side of the top plate 18 in FIG. 3), which is opposite to the first end 18A side, of the top plate 18 in the X direction, and the other end part 124T thereof is a free end.

Each of the first fixing belt 104 and the second fixing belt 124 is formed of a material that is easily bent. The end part 104R of the first fixing belt 104 and the end part 124R of the second fixing belt 124 are disposed at the same position of the top plate 18 in the Z direction. The first fixing belt 104 and the second fixing belt 124 are configured to have the same length in the Z direction. Further, in the first fixing belt 104 and the second fixing belt 124, a length from the end part 104R to the end part 104T is configured to be the same as a length from the end part 124R to the end part 124T. That is, the first fixing belt 104 and the second fixing belt 124 have the same shape and are disposed in left-right symmetry with respect to the top plate 18.

The first fixing belt 104 and the second fixing belt 124 may be disposed on the top plate 18 via a slide mechanism that enables the first fixing belt 104 and the second fixing belt 124 to be movable in the Z direction, respectively. Further, the first fixing belt 104 and the second fixing belt 124 may be configured as a single belt fixed to the top plate 18, and both ends of the single belt may be the end part 104T and the end part 124T.

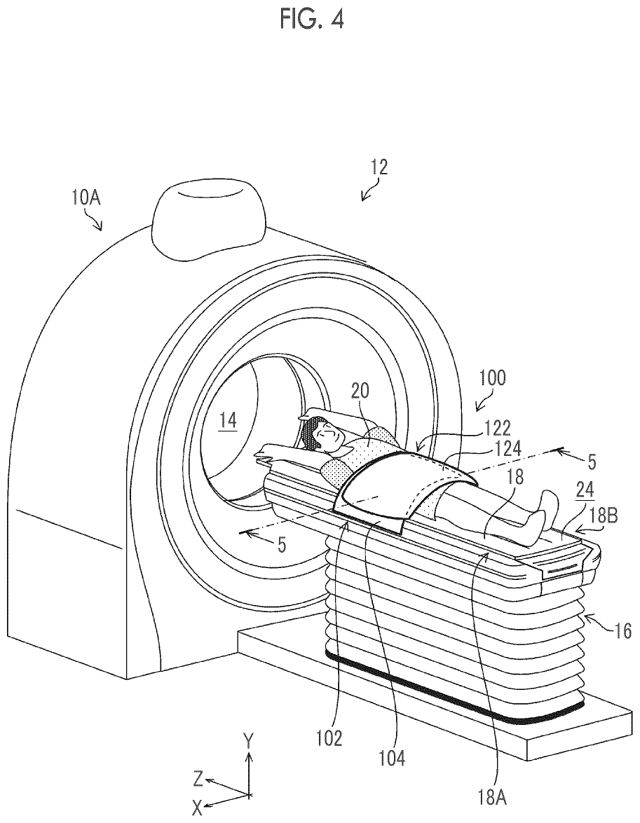

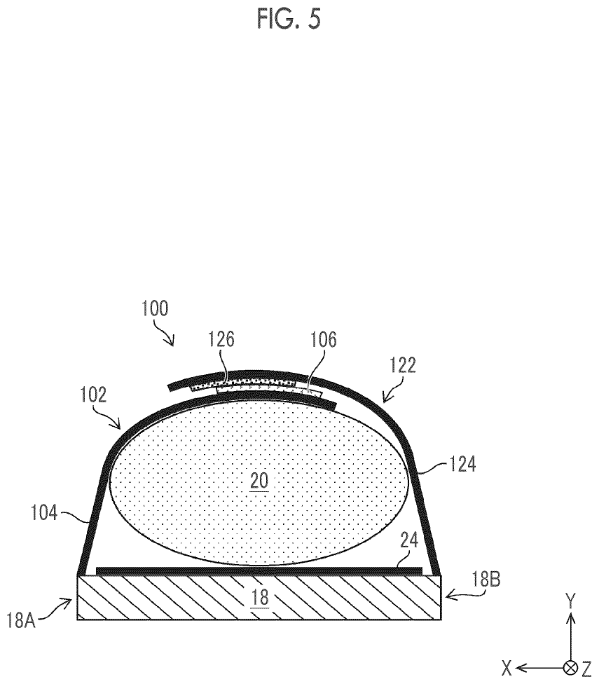

FIG. 4 is a perspective view of an example of the MRI apparatus 10A, and shows a state in which the subject 20 is fixed to the top plate 18 by the RF coil 100. Further, FIG. 5 is a sectional view taken along a line 5-5 of FIG. 4. In a case where the subject 20 is fixed to the top plate 18, first, the user mounts the first fixing belt 104 on the examination target site (abdomen herein) of the subject 20 placed on the top plate 18 from the first end 18A side toward the second end 18B side of the top plate 18. Next, the user mounts the second fixing belt 124 on the subject 20 in a state in which at least a part of the second fixing belt 124 is overlapped with the first fixing belt 104 from the second end 18B side toward the first end 18A side of the top plate 18.

A surface of the first fixing belt 104 in contact with the second fixing belt 124 and a surface of the second fixing belt 124 in contact with the first fixing belt 104 are respectively provided with a first surface 106 and a second surface 126 (not shown in FIG. 4) of a surface fastener. The surface fastener is a bonding member in which a pair of hook surfaces and loop surfaces engage with each other. For example, the first surface 106 is the hook surface and the second surface 126 is the loop surface. The first fixing belt 104 and the second fixing belt 124 are attachably and detachably bonded to each other by the first surface 106 and the second surface 126 of the surface fastener in an overlap region where the first fixing belt 104 and the second fixing belt 124 are overlapped with each other.

The bonding member that bonds the first fixing belt 104 and the second fixing belt 124 is not limited to the surface fastener, and a known buckle or the like may be used in which a bonding position is adjustable.

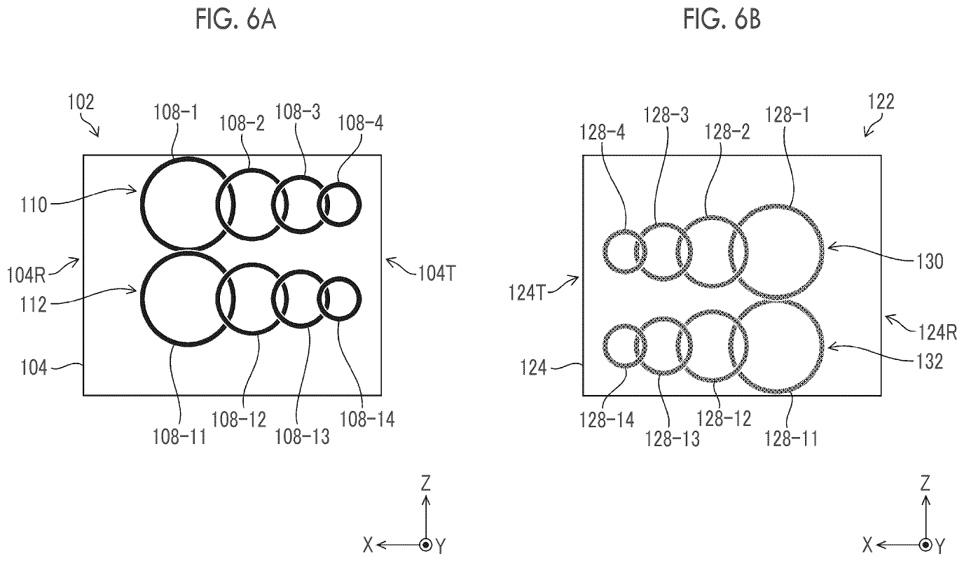

FIGS. 6A and 6B are planar perspective views of the first coil unit 102 and the second coil unit 122.

FIG. 6A shows a state in which the first coil unit 102 is placed on the top plate 18 (not shown in FIGS. 6A and 6B). As shown in FIG. 6A, in the first coil unit 102, a plurality of elements 108-1, 108-2, 108-3, 108-4, 108-11, 108-12, 108-13, and 108-14 having a planar shape are disposed on the first fixing belt 104. The shapes of the elements 108-1, 108-2, 108-3, 108-4, 108-11, 108-12, 108-13, and 108-14 are circular in a plan view, respectively.

The elements 108-1 to 108-4 form a first outer peripheral region 110 in which respective parts of the elements 108-1 to 108-4 are overlapped with each other and are continuously disposed along the X direction in a plan view of the first fixing belt 104. Here, respective parts of the element 108-1 and the element 108-2 are overlapped with each other, respective parts of the element 108-2 and the element 108-3 are overlapped with each other, and respective parts of the element 108-3 and the element 108-4 are overlapped with each other.

Similarly, the elements 108-11 to 108-14 form a first outer peripheral region 112 in which respective parts of the elements 108-11 to 108-14 are overlapped with each other and are continuously disposed along the X direction.

As described above, the first coil unit 102 has two rows of the first outer peripheral regions 110 and 112 that are parallel to the X direction. The first outer peripheral regions 110 and 112 have a tapered shape, as a whole, as being spaced from the first end 18A side of the top plate 18, that is, from the end part 104R of the first fixing belt 104 toward the end part 104T thereof.

Each of the elements 108-1 to 108-4 has a diameter that decreases from the end part 104R of the first fixing belt 104 toward the end part 104T thereof. That is, the diameters of the elements 108-1 to 108-4 are smaller in an order of 108-1, 108-2, 108-3, and 108-4. Further, the respective elements 108-1 to 108-4 are disposed at positions at which a line connecting centers thereof is parallel to the X direction.

Similarly, each of the elements 108-11 to 108-14 has a diameter that decreases from the end part 104R of the first fixing belt 104 toward the end part 104T thereof. Further, the respective elements 108-11 to 108-14 are disposed at positions at which a line connecting centers thereof is parallel to the X direction.

FIG. 6B shows a state in which the second coil unit 122 is placed on the top plate 18. As shown in FIG. 6B, in the second coil unit 122, a plurality of elements 128-1, 128-2, 128-3, 128-4, 128-11, 128-12, 128-13, and 128-14 having a planar shape are disposed on the second fixing belt 124. The shapes of the elements 128-1, 128-2, 128-3, 128-4, 128-11, 128-12, 128-13, and 128-14 are circular in a plan view, respectively.

The elements 128-1 to 128-4 form a second outer peripheral region 130 in which respective parts of the elements 128-1 to 128-4 are overlapped with each other and are continuously disposed along the X direction in a plan view of the second fixing belt 124. Similarly, the elements 128-11 to 128-14 form a second outer peripheral region 132 in which respective parts of the elements 128-11 to 128-14 are overlapped with each other and are continuously disposed along the X direction.

As described above, the second coil unit 122 has two rows of the second outer peripheral regions 130 and 132 that are parallel to the X direction. The second outer peripheral regions 130 and 132 have a tapered shape as being spaced from the second end 18B side of the top plate 18, that is, from the end part 124R of the second fixing belt 124 toward the end part 124T thereof.

Each of the elements 128-1 to 128-4 has a diameter that decreases from the end part 124R of the second fixing belt 124 toward the end part 124T thereof. That is, the diameters of the elements 128-1 to 128-4 are smaller in an order of 128-1, 128-2, 128-3, and 128-4. Further, the respective elements 128-1 to 128-4 are disposed at positions at which a line connecting centers thereof is parallel to the X direction.

Similarly, each of the elements 128-11 to 128-14 has a diameter that decreases from the end part 124R of the second fixing belt 124 toward the end part 124T thereof. Further, the respective elements 128-11 to 128-14 are disposed at positions at which a line connecting centers thereof is parallel to the X direction.

The first outer peripheral regions 110 and 112 of the first coil unit 102 and the second outer peripheral regions 130 and 132 of the second coil unit 122 are disposed with phases in the Z direction being shifted from each other. The first outer peripheral regions 110 and 112 of the first coil unit 102 and the second outer peripheral regions 130 and 132 of the second coil unit 122 are alternately disposed along the Z direction. In the example shown in FIGS. 6A and 6B, the first outer peripheral region 110, the second outer peripheral region 130, the first outer peripheral region 112, and the second outer peripheral region 132 are alternately disposed in an order from a top to a bottom in FIGS. 6A and 6B.

### Shape of Outer Peripheral Region

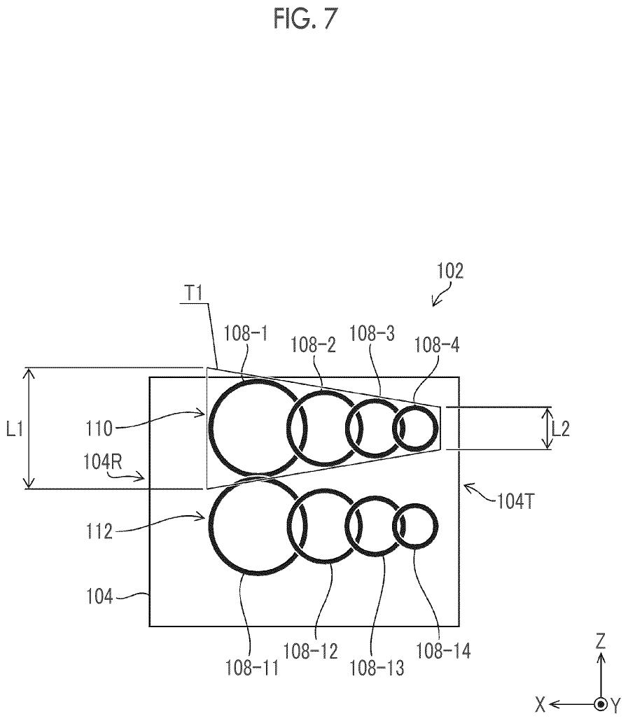

FIG. 7 is a view for describing the shape of the outer peripheral region. Here, the first outer peripheral region 110 formed by the elements 108-1 to 108-4 will be described as an example.

For the first outer peripheral region 110, a trapezoid T1 having one set of two opposite sides parallel to the Z direction, which encompasses the first outer peripheral region 110 and has a smallest area, is set. In a case where a side on the end part 104R side of the first fixing belt 104, out of the two sides parallel to the Z direction of the trapezoid T1 set for the first outer peripheral region 110, is larger than a side on the end part 104T side thereof, which is a free end, the first outer peripheral region 110 has a tapered shape as being spaced from the first end 18A side of the top plate 18, that is, from the end part 104R of the first fixing belt 104 toward the end part 104T thereof. Since L1>L2 in the trapezoid T1 shown in FIG. 7, the first outer peripheral region 110 has a tapered shape.

Further, in a case of the second outer peripheral region 130, a trapezoid having one set of two opposite sides parallel to the Z direction, which encompasses the second outer peripheral region 130 and has a smallest area, is set. In a case where a side on the end part 124R side of the second fixing belt 124, out of the two sides parallel to the Z direction of the trapezoid set for the second outer peripheral region 130, is larger than a side on the end part 124T side thereof, which is a free end, the second outer peripheral region 130 has a shape that tapers from the end part 124R of the second fixing belt 124 toward the end part 124T thereof.

In the first coil unit 102 and the second coil unit 122 shown in FIGS. 6A and 6B, each of the first outer peripheral region 112, the second outer peripheral regions 130 and 132 has a small side on the free end side and thus has a tapered shape.

### Subject Size and Element Disposition

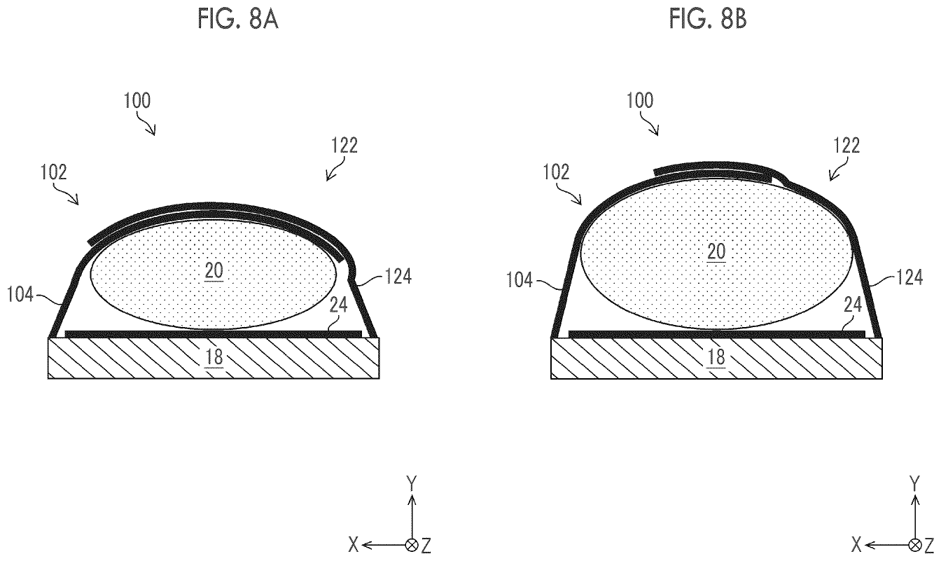

FIGS. 8A and 8B are schematic views of a state in which the subject 20 is fixed to the top plate 18 by the RF coil 100, and is a sectional view similar to FIG. 5. In FIGS. 8A and 8B, the surface fastener is not illustrated. FIG. 8A shows a case where the subject 20 having a relatively thin body shape (size) is fixed to the top plate 18. Further, FIG. 8B shows a case where the subject 20 having a relatively thick size is fixed to the top plate 18. As shown in FIGS. 8A and 8B, an overlapping length of the first fixing belt 104 and the second fixing belt 124 changes according to the size of the subject 20.

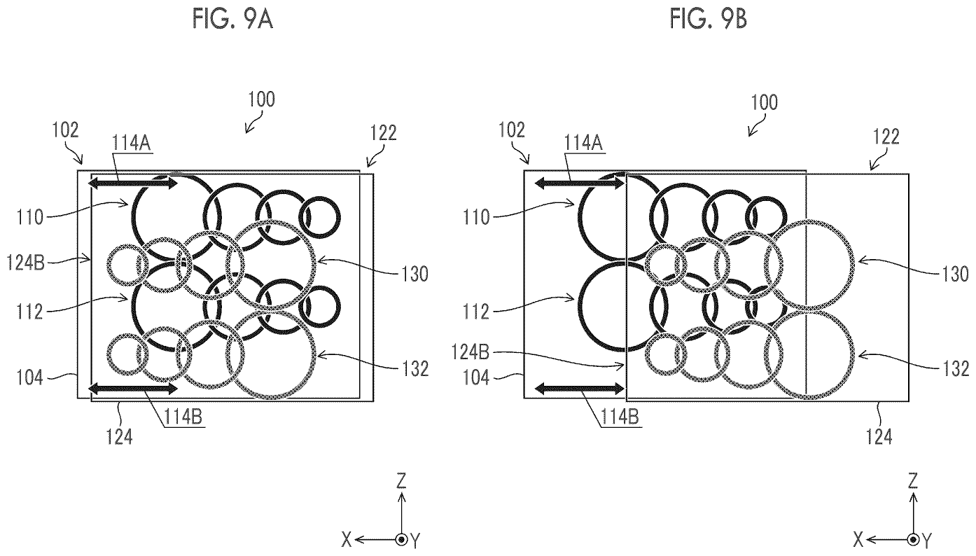

FIGS. 9A and 9B are planar perspective views of a disposition of elements in a state in which the subject 20 is fixed to the top plate 18 by the RF coil 100, and is a view of the state of FIGS. 8A and 8B as viewed from the Y direction side. FIGS. 9A and 9B show the first fixing belt 104 and the second fixing belt 124 to be expanded in the X direction.

FIG. 9A shows a case where the subject 20 having a relatively thin size is fixed to the top plate 18. Further, FIG. 9B shows a case where the subject 20 having a relatively thick size is fixed to the top plate 18. As shown in FIGS. 9A and 9B, in a state in which the RF coil 100 is mounted on the subject 20, the first outer peripheral regions 110 and 112 disposed in a comb shape on the first fixing belt 104 and the second outer peripheral regions 130 and 132 disposed in a comb shape on the second fixing belt 124 are disposed to face each other in a nested manner in the Z direction without a gap.

Here, positions at which the first outer peripheral regions 110 and 112 and the second outer peripheral regions 130 and 132 are overlapped with each other are changed according to the size of the subject 20, and thus a coil size of the subject 20 in a circumferential direction (X direction in FIGS. 9A and 9B) is changed in gradation.

### Effects

With the RF coil 100, it is possible to fix the subject 20 to the top plate 18 and to set and clean up the RF coil only by the operation of the first fixing belt 104 and the second fixing belt 124, and thus it is possible to improve the workflow.

With the RF coil 100, even in a case where the overlapping position of the first fixing belt 104 and the second fixing belt 124 is changed according to the size of the subject 20, a gap between the elements is unlikely to be formed. Accordingly, it is possible to appropriately cover the examination site of the subject 20 with the element, regardless of the size of the subject 20.

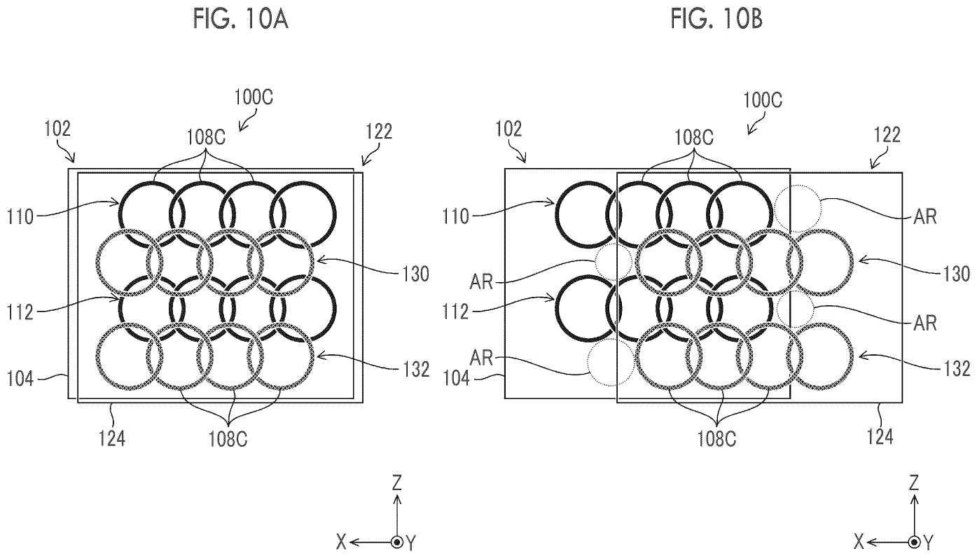

FIGS. 10A and 10B are comparative views for describing the effect of the first embodiment, and shows an RF coil 100C. The RF coil 100C comprises a plurality of elements 108C having a constant diameter, and other configurations thereof are the same as those of the RF coil 100. As in FIGS. 9A and 9B, FIGS. 10A and 10B show a disposition of elements in a state in which the subject 20 is fixed to the top plate 18 by the RF coil 100C in a manner that the first fixing belt 104 and the second fixing belt 124 are expanded in the X direction.

FIG. 10A shows a case where the subject 20 having a relatively thin size is fixed to the top plate 18. Further, FIG. 10B shows a case where the subject 20 having a relatively thick size is fixed to the top plate 18. As shown in F10A, in the RF coil 100C, the elements 108C are disposed such that the examination site of the subject 20 having the relatively thin size can be appropriately covered with the elements 108C. However, as shown in F10B, in a case of the subject 20 having the relatively thick size, there is a region AR where the examination site is not covered with the element 108C. In the region AR, the SNR of the magnetic resonance signal is reduced, which is not preferable.

With the RF coil 100 according to the first embodiment, it is possible to prevent the SNR reduction in a region not covered with the element in a case of the subject 20 having the relatively thick size, for the RF coil 100C shown in FIGS. 10A and 10B.

An appropriate range of the size of the subject 20 in which the effect of the RF coil 100 is exhibited is a range in which a relatively large gap is not formed between the elements. Therefore, it is preferable that a guide display showing an appropriate range of an overlapping amount of the first fixing belt 104 and the second fixing belt 124 is provided in the first fixing belt 104 and thus the user can check whether or not the overlapping amount is within the appropriate range at the time of setting.

Bidirectional arrows 114A and 114B shown in FIGS. 9A and 9B are an example of the guide display showing the appropriate range of the overlapping amount. In a case where the second fixing belt 124 is overlapped with the first fixing belt 104 and a position of the end part 124T of the second fixing belt 124 is within a range of the bidirectional arrows 114A and 114B, the overlapping amount of the first fixing belt 104 and the second fixing belt 124 is appropriate. The guide display is not limited to the bidirectional arrows 114A and 114B, and it is sufficient that the user can recognize the appropriate range of the overlapping amount.

### Second Embodiment

### Configuration of RF Coil

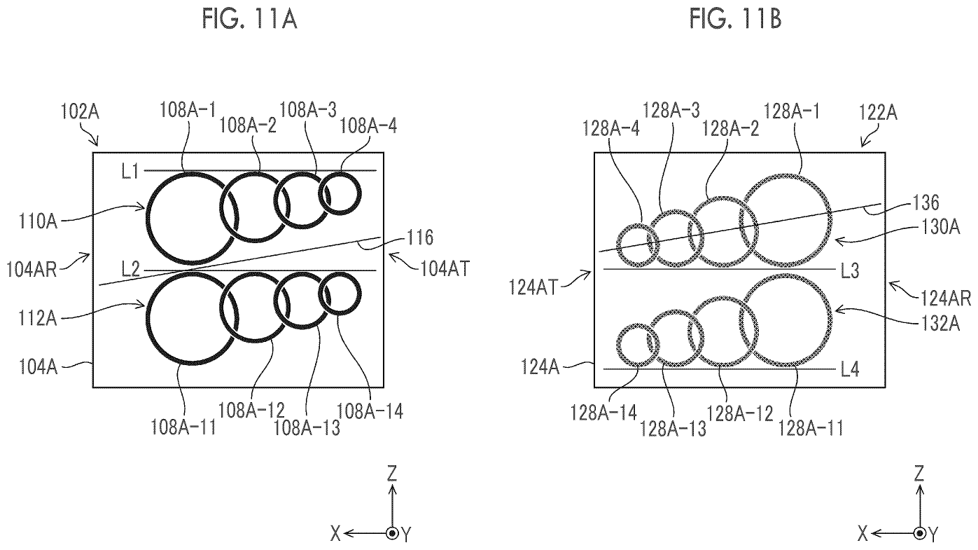

FIGS. 11A and 11B are planar perspective views of a first coil unit 102A and a second coil unit 122A according to a second embodiment.

FIG. 11A shows a state in which the first coil unit 102A is placed on the top plate 18 (not shown in FIGS. 11A and 11B). As shown in FIG. 11A, the first coil unit 102A comprises a plurality of elements 108A-1, 108A-2, 108A-3, 108A-4, 108A-11, 108A-12, 108A-13, and 108A-14 that are two-dimensionally disposed on the first fixing belt 104A.

The elements 108A-1 to 108A-4 form a first outer peripheral region 110A in which respective parts of the elements 108A-1 to 108A-4 are overlapped with each other and are continuously disposed along the X direction in a plan view of the first fixing belt 104A. Similarly, the elements 108A-11 to 108A-14 form a first outer peripheral region 112A in which respective parts of the elements 108A-11 to 108A-14 are overlapped with each other and are continuously disposed along the X direction.

In the first outer peripheral region 110A, the elements 108A-1 to 108A-4 have diameters that decrease from an end part 104AR side of the first fixing belt 104 fixed to the first end 18A side of the top plate 18 toward an end part 104AT side, which is a free end. Similarly, in the first outer peripheral region 112A, the elements 108A-11 to 108A-14 have diameters that decrease from the end part 104AR side toward the end part 104AT side.

The respective elements 108A-1 to 108A-4 and 108A-11 to 108A-14 are disposed in a top-aligned manner in FIGS. 11A and 11B. That is, the respective elements 108A-1, 108A-2, 108A-3, and 108A-4 are disposed with the end parts thereof aligned to be in contact with a straight line L1 that is on one side (upper side in FIGS. 11A and 11B) in the Z direction with respect to the elements 108A-1 to 108A-4 and is parallel to the X direction. Further, the respective elements 108A-11, 108A-12, 108A-13, and 108A-14 are disposed with the end parts thereof aligned to be in contact with a straight line L2 that is on one side (upper side in FIGS. 11A and 11B) in the Z direction with respect to the elements 108A-11 to 108A-14 and is parallel to the X direction. Further, a guide line 116 is provided in the first fixing belt 104A. The guide line 116 is provided at a position that equally divides a spacing between the first outer peripheral regions 110A and 112A.

FIG. 11B shows a state in which the second coil unit 122A is placed on the top plate 18. As shown in FIG. 11B, the second coil unit 122A comprises a plurality of elements 128A-1, 128A-2, 128A-3, 128A-4, 128A-11, 128A-12, 128A-13, and 128A-14 that are two-dimensionally disposed on the second fixing belt 124A.

The elements 128A-1 to 128A-4 form a second outer peripheral region 130A in which respective parts of the elements 128A-1 to 128A-4 are overlapped with each other and are continuously disposed along the X direction in a plan view of the second fixing belt 124. Similarly, the elements 128A-11 to 128A-14 form a second outer peripheral region 132A in which respective parts of the elements 128A-11 to 128A-14 are overlapped with each other and are continuously disposed along the X direction.

In the second outer peripheral region 130A, the elements 128A-1 to 128A-4 have diameters that decrease from the end part 124R side of the second fixing belt 124 fixed to the second end 18B side of the top plate 18 toward the other end part 124T side. Similarly, in the second outer peripheral region 132A, the elements 128A-11 to 128A-14 have diameters that decrease from the end part 124R side toward the other end part 124T side.

The respective elements 128A-1 to 128A-4 and 128A-11 to 128A-14 are disposed in a bottom-aligned manner in FIGS. 11A and 11B. That is, the respective elements 128A-1, 128A-2, 128A-3, and 128A-4 are disposed with the end parts thereof aligned to be in contact with a straight line L3 that is on the other side (lower side in FIGS. 11A and 11B) in the Z direction with respect to the elements 128A-1 to 128A-4 and is parallel to the X direction. Further, the respective elements 128A-11, 128A-12, 128A-13, and 128A-14 are disposed with the end parts thereof aligned to be in contact with a straight line L4 that is on the other side (lower side in FIGS. 11A and 11B) in the Z direction with respect to the elements 128A-11 to 128A-14 and is parallel to the X direction.

The first outer peripheral regions 110A and 112A of the first coil unit 102A and the second outer peripheral regions 130A and 132A of the second coil unit 122A are alternately disposed along the Z direction of the top plate 18. In the example shown in FIGS. 11A and 11, the first outer peripheral region 110A, the second outer peripheral region 130A, the first outer peripheral region 112A, and the second outer peripheral region 132A are alternately disposed in an order from a top to a bottom in FIGS. 11A and 11B.

Further, a guide line 136 is provided in the second fixing belt 124A. The guide line 136 is provided at a position passing through centers of the respective elements 128A-1, 128A-2, 128A-3, and 128A-4 constituting the second outer peripheral region 130A.

### Shape of Outer Peripheral Region

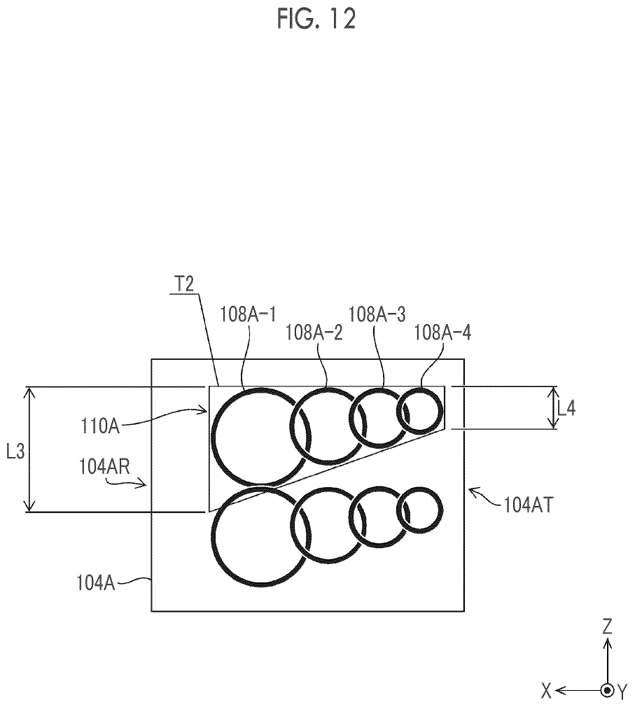

FIG. 12 is a view for describing the shape of the outer peripheral region. Here, the first outer peripheral region 110A formed by the elements 108A-1 to 108A-4 will be described as an example.

For the first outer peripheral region 110A, a trapezoid T2 having one set of two opposite sides parallel to the Z direction, which encompasses the first outer peripheral region 110A and has a smallest area, is set. As shown in FIG. 12, in the trapezoid T2 set for the first outer peripheral region 110A, out of two sides parallel to the Z direction of the trapezoid T2, a length L3 of a side on the end part 104AR side of the first fixing belt 104A is larger than a length L4 of a side on the end part 104AT side thereof, which is a free end. Therefore, the first outer peripheral region 110A has a tapered shape. Similarly, each of the first outer peripheral region 112A, the second outer peripheral regions 130A and 132A has a small side on the free end side and thus has a tapered shape.

### Subject Size and Element Disposition

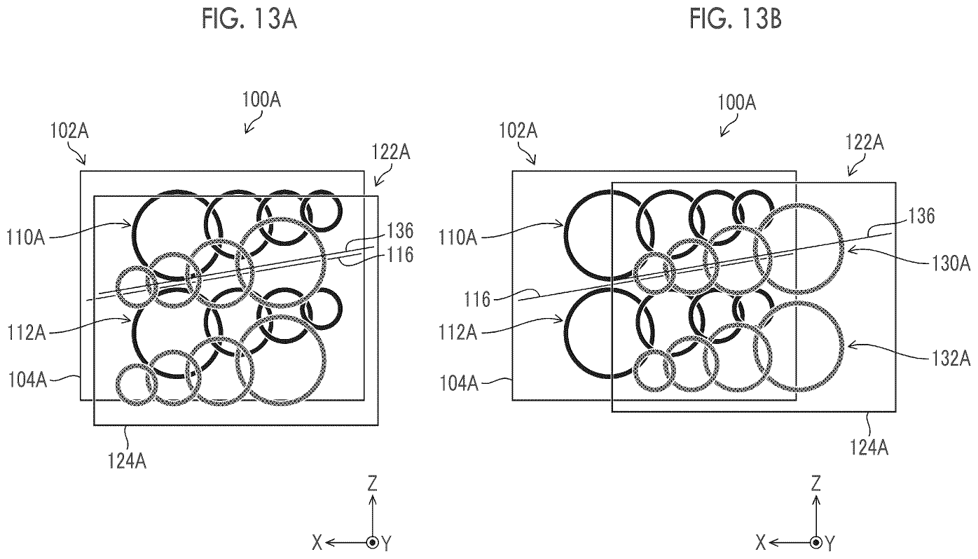

FIGS. 13A and 13B are planar perspective views of an element disposition in a state in which the subject 20 is fixed to the top plate 18 by the RF coil 100A comprising the first coil unit 102A and the second coil unit 122A. FIGS. 13A and 13B show the first fixing belt 104A and the second fixing belt 124A to be expanded in the X direction, as in FIGS. 9A and 9B.

FIG. 13A shows a case where the subject 20 having a relatively thin size is fixed to the top plate 18. Further, FIG. 13B shows a case where the subject 20 having a relatively thick size is fixed to the top plate 18. Here, the second fixing belt 124A is overlapped with the first fixing belt 104A such that the guide line 116 is overlapped with the guide line 136. That is, the guide lines 116 and 136 are provided to dispose the other side (lower side in FIGS. 13A and 13B) of the first outer peripheral region 110A and one side (upper side in FIGS. 13A and 13B) of the second outer peripheral region 130A at positions adjacent to each other in a plan view and to dispose the other side (lower side in FIGS. 13A and 13B) of the first outer peripheral region 112A and one side (upper side in FIGS. 13A and 13B) of the second outer peripheral region 132A at positions adjacent to each other in a plan view. In the example shown in FIG. 13A, since the guide line 116 is overlapped with the guide line 136, the first fixing belt 104A and the second fixing belt 124A are overlapped with a shift in a position in the Z direction.

As shown in FIGS. 13A and 13B, the positions at which the first outer peripheral regions 110A and 112A and the second outer peripheral regions 130A and 132A are overlapped with each other are changed according to the size of the subject 20, and thus the coil size in the X direction is changed in gradation.

### Effects

With the RF coil 100A, the elements are disposed in a top-aligned manner on the first fixing belt 104A and in a bottom-aligned manner on the second fixing belt 124A with respect to the direction in which the diameter of the element decreases, that is, the circumferential direction of the subject 20 (X direction in FIGS. 11A and 11B), and thus, in a case where the first fixing belt 104 is overlapped with the second fixing belt 124, a distribution of the elements is not oblique with respect to the X direction.

In the RF coil 100A, a change direction of an overlapping condition of the first fixing belt 104 and the second fixing belt 124 according to the size of the subject 20 is an arrangement direction of the elements, and is an oblique direction with respect to the X direction. With the RF coil 100A, even in a case where the size of the subject 20 is different, the user overlaps the first fixing belt 104A with the second fixing belt 124A such that the guide line 116 matches the guide line 136 with the display of the guide lines 116 and 136 on the first fixing belt 104 and the second fixing belt 124 such that the user can recognize the arrangement direction of the elements, and thus it is possible to appropriately dispose the first outer peripheral regions 110A and 112A and the second outer peripheral regions 130A and 132A with respect to the subject 20.

The display that enables the user to recognize the arrangement direction of the elements is not limited to the guide lines, and may be a display that enables the first fixing belt 104 and the second fixing belt 124 to be overlapped with each other such that the user appropriately disposes the first outer peripheral regions 110A and 112A and the second outer peripheral regions 130A and 132A.

### Third Embodiment

### Configuration of RF Coil

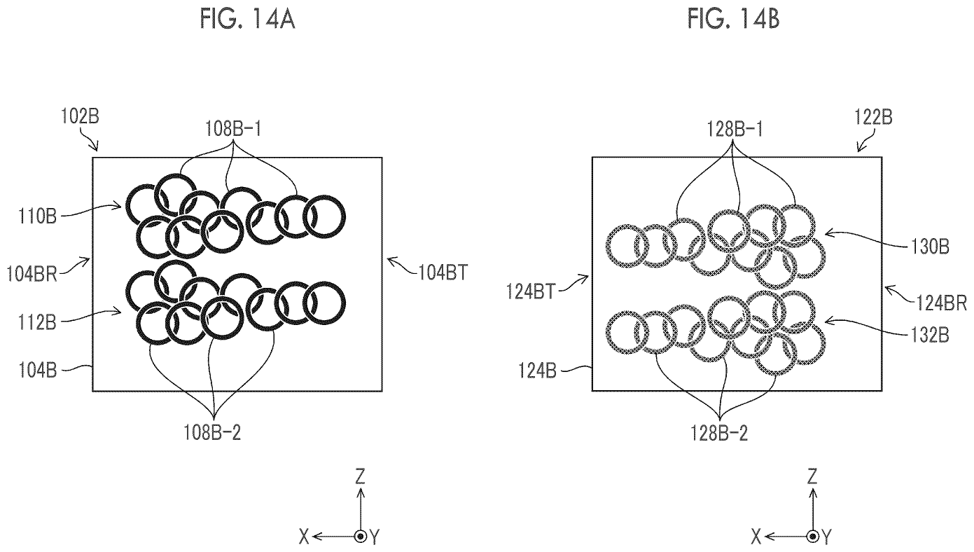

FIGS. 14A and 14B are planar perspective views of a first coil unit 102B and a second coil unit 122B according to a third embodiment.

FIG. 14A shows a state in which the first coil unit 102B is placed on the top plate 18 (not shown in FIGS. 14A and 14B). As shown in FIG. 14A, the first coil unit 102B comprises a plurality of elements 108B-1 and 108B-2 that are two-dimensionally disposed on the first fixing belt 104B.

Each of the plurality of elements 108B-1 has a constant diameter. Further, the plurality of elements 108B-1 form a first outer peripheral region 110B in which respective parts of the plurality of elements 108B-1 are overlapped with each other and are continuously disposed along the X direction in a plan view of the first fixing belt 104B. Similarly, each of the plurality of elements 108B-2 has a constant diameter, and the plurality of elements 108B-2 form a first outer peripheral region 112B in which respective parts of the plurality of elements 108B-2 are overlapped with each other and are continuously disposed along the X direction.

In the first outer peripheral region 110B, the number of elements 108B-1 per unit area decreases from an end part 104BR side, which is fixed to the top plate 18 of the first fixing belt 104B, toward an end part 104BT side, which is a free end. Similarly, in the first outer peripheral region 112B, the number of elements 108B-2 per unit area decreases from an end part 124BR side toward an end part 124BT side.

FIG. 14B shows a state in which the second coil unit 122B is placed on the top plate 18. As shown in FIG. 14B, the second coil unit 122B comprises a plurality of elements 128B-1 and 128B-2 that are two-dimensionally disposed on the second fixing belt 124B.

Each of the plurality of elements 128B-1 has a constant diameter. Further, the plurality of elements 128B-1 form a second outer peripheral region 130B in which respective parts of the plurality of elements 128B-1 are overlapped with each other and are continuously disposed along the X direction in a plan view of the second fixing belt 124B. Similarly, each of the plurality of elements 128B-2 has a constant diameter, and the plurality of elements 128B-2 form a second outer peripheral region 132B in which respective parts of the plurality of elements 128B-2 are overlapped with each other and are continuously disposed along the X direction.

In the second outer peripheral region 130B, the number of elements 128B-1 per unit area decreases from the end part 124BR side of the second fixing belt 124B toward the end part 124BT side thereof. Similarly, in the second outer peripheral region 132B, the number of elements 128B-2 per unit area decreases from the end part 124BR side toward the end part 124BT side.

The first outer peripheral regions 110B and 112B of the first coil unit 102B and the second outer peripheral regions 130B and 132B of the second coil unit 122B are alternately disposed along the Z direction of the top plate 18. In the example shown in FIGS. 14A and 14B, the first outer peripheral region 110B, the second outer peripheral region 130B, the first outer peripheral region 112B, and the second outer peripheral region 132B are alternately disposed in an order from a top to a bottom in FIGS. 14A and 14B.

### Shape of Outer Peripheral Region

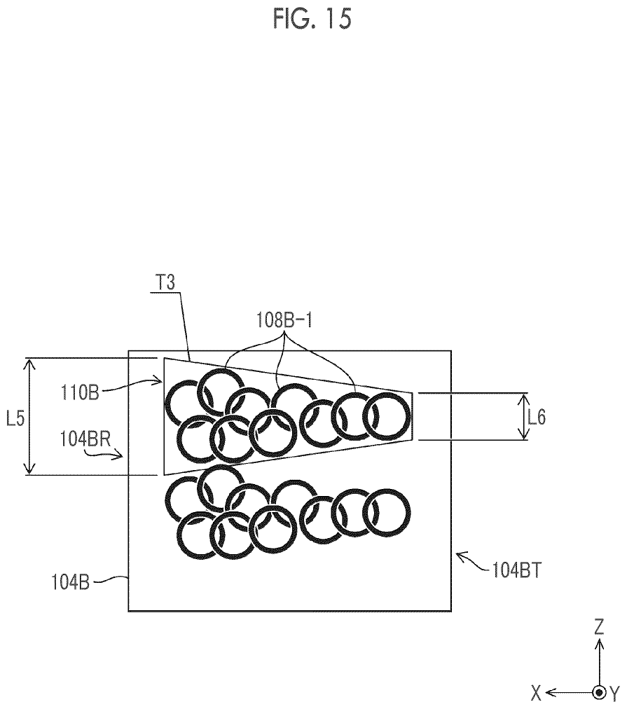

FIG. 15 is a view for describing the shape of the outer peripheral region. Here, the first outer peripheral region 110B formed by the plurality of elements 108B-1 will be described as an example.

For the first outer peripheral region 110B, a trapezoid T3 having one set of two opposite sides parallel to the Z direction, which encompasses the first outer peripheral region 110B and has a smallest area, is set. As shown in FIG. 15, in the trapezoid T3 set for the first outer peripheral region 110B, out of two sides parallel to the Z direction of the trapezoid T3, a length L5 of a side on the end part 104BR side of the first fixing belt 104B is larger than a length L6 of a side on the end part 104BT side thereof, which is a free end. Therefore, the first outer peripheral region 110B has a tapered shape. Similarly, each of the first outer peripheral region 112B, the second outer peripheral regions 130B and 132B has a small side on the free end side and thus has a tapered shape.

### Subject Size and Element Disposition

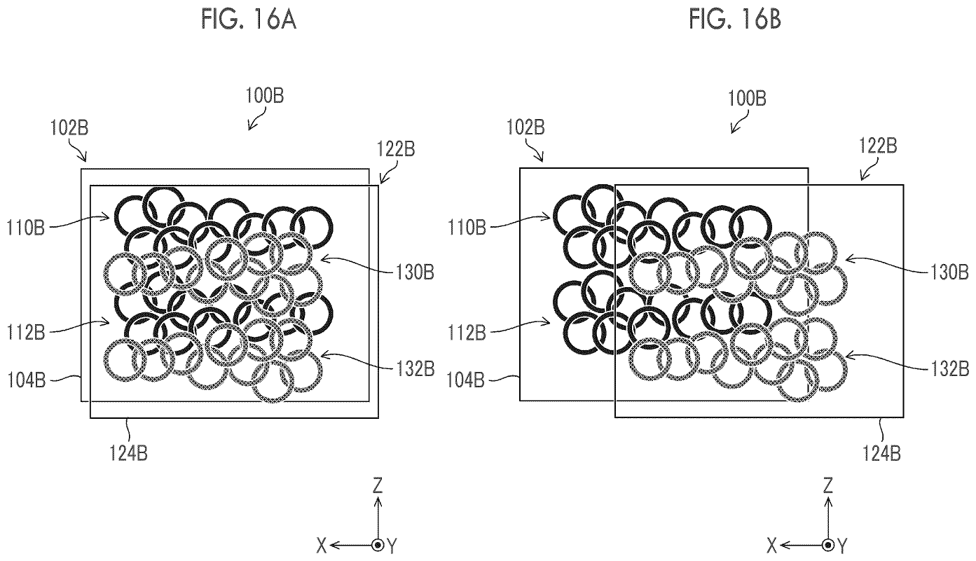

FIGS. 16A and 16B are planar perspective views of an element disposition in a state in which the subject 20 is fixed to the top plate 18 by the RF coil 100B comprising the first coil unit 102B and the second coil unit 122B. FIGS. 16A and 16B show the first fixing belt 104B and the second fixing belt 124B to be expanded in the X direction, as in FIGS. 9A and 9B.

FIG. 16A shows a case where the subject 20 having a relatively thin size is fixed to the top plate 18. Further, FIG. 16B shows a case where the subject 20 having a relatively thick size is fixed to the top plate 18.

As shown in FIGS. 16A and 16B, the positions where the first outer peripheral regions 110B and 112B and the second outer peripheral regions 130B and 132B are overlapped with each other are changed according to the size of the subject 20, and thus the coil size in the X direction is changed in gradation.

### Effects

With the RF coil 100B, even in a case where the diameters of the elements are constant, the elements are disposed in the region having the tapered shape, as in the first outer peripheral regions 110 and 112 and the second outer peripheral regions 130 and 132 of the first embodiment, and thus it is possible to obtain the same effect as that of the first embodiment. Further, with the RF coil 100B, since the diameters of the elements are constant, it is possible to reduce management costs by unifying components.

Here, the case has been described in which the number of rows of the coil regions in the first coil unit 102B and the second coil unit 122B is the same. However, the RF coil 100B may have the first coil region of the first coil unit 102B in two rows and the second coil region of the second coil unit 122B in one row or three rows. Accordingly, it is possible to obtain an optimum sensitivity region for a target site. The same applies to the RF coil 100 according to the first embodiment and the RF coil 100A according to the second embodiment.

### Others

The technical scope of the present invention is not limited to the range described in the above-described embodiments. The configurations and the like in each embodiment can be appropriately combined between the respective embodiments without departing from the gist of the present invention.

### EXPLANATION OF REFERENCES

10: MRI apparatus
12: gantry
14: bore
16: bed
18: top plate
20: subject
22: fixing belt
100, 100A, 100B, 100C: RF coil
102, 102A, 102B: first coil unit
122, 122A, 122B: second coil unit

What is claimed is:

1. A radio frequency (RF) coil for a magnetic resonance imaging apparatus including a top plate on which a subject is placed along a longitudinal direction, the RF coil comprising:
a first coil unit including
a first fixing belt that is disposed on the top plate and is mounted on the subject from a first end side of the top plate in a width direction orthogonal to the longitudinal direction toward a second end side opposite to the first end side, and
a plurality of elements that are disposed on the first fixing belt; and
a second coil unit including
a second fixing belt that is disposed on the top plate and is mounted on the subject in a manner that at least a part of the second fixing belt is overlapped with the first fixing belt from the second end side of the top plate toward the first end side, and
a plurality of elements that are disposed on the second fixing belt,
wherein a first outer peripheral region formed by the plurality of elements of the first coil unit has a tapered shape as being spaced from the first end side of the top plate,
a second outer peripheral region formed by the plurality of elements of the second coil unit has a tapered shape as being spaced from the second end side of the top plate, and
the first outer peripheral region and the second outer peripheral region are disposed with phases in the longitudinal direction being shifted from each other.

2. The RF coil according to claim 1,
wherein the plurality of elements of the first coil unit form a plurality of the first outer peripheral regions,
the plurality of elements of the second coil unit form a plurality of the second outer peripheral regions, and
the plurality of the first outer peripheral regions and the plurality of the second outer peripheral regions are alternately disposed along the longitudinal direction.

3. The RF coil according to claim 1,
wherein each of the plurality of elements has a diameter that decreases as being spaced from the top plate.

4. The RF coil according to claim 3,
wherein the plurality of elements are disposed at positions at which a line connecting centers of the plurality of elements is parallel to the width direction.

5. The RF coil according to claim 3,
wherein the plurality of elements of the first coil unit are disposed such that end parts of the plurality of elements are aligned with each other on one side in the longitudinal direction, and
the plurality of elements of the second coil unit are disposed such that end parts of the plurality of elements are aligned with each other on the other side in the longitudinal direction.

6. The RF coil according to claim 5,
wherein the first fixing belt and the second fixing belt respectively include guide lines to dispose, in a case where the first fixing belt and the second fixing belt are mounted on the subject, the other side of the first outer peripheral region and the one side of the second outer peripheral region at positions adjacent to each other in a plan view.

7. The RF coil according to claim 1,
wherein each of the plurality of elements has a constant diameter, and is disposed such that the number of elements per unit area decreases as being spaced from the top plate.

8. The RF coil according to claim 1,
wherein the first fixing belt includes a guide display showing an appropriate range of a position where the second fixing belt overlaps.

9. The RF coil according to claim 1,
wherein the first fixing belt and the second fixing belt include a first surface and a second surface of a pair of surface fasteners with which the first surface and the second surface engage, at positions where the first fixing belt and the second fixing belt are in contact with each other in a case of being mounted on the subject.

10. Abed device comprising:
a top plate on which a subject is placed; and
the RF coil according to claim 1.

11. A magnetic resonance imaging apparatus comprising:
the bed device according to claim 10;
a gantry including a magnetic field generation source and having an opening; and
a drive mechanism that moves the top plate in the longitudinal direction to cause the top plate to enter the opening of the gantry and exit from the opening of the gantry.
